(19) United States
(12) Patent Application Publication
(10) Pub. No.: US 2025/0122614 A1
(43) Pub. Date: Apr. 17, 2025

(54) NON-STICK COATING AND MANUFACTURING PROCESS

(71) Applicant: Joanneum Research Forschungsgesellschaft mbH, Graz (AT)

(72) Inventors: Barbara Stadlober, Graz (AT); Anna Maria Coclite, Graz (AT); Dieter Nees, Thannhausen (AT); Jasmin Pfleger, St. Jakob im Walde (AT)

(21) Appl. No.: 18/904,699

(22) Filed: Oct. 2, 2024

(30) Foreign Application Priority Data
Oct. 11, 2023 (EP) 23203074.2

(51) Int. Cl. C23C 16/44; C09D 7/63; C09D 133/16

(52) U.S. Cl. CPC C23C 16/44; C09D 7/63; C09D 133/16

(57) ABSTRACT

A process for producing a non-stick coated substrate which comprises applying a non-stick compound to a substrate by chemical vapor deposition, wherein the non-stick compound is a surface active compound having a polymerizable group and the substrate is metal-containing and modified with an adhesion promoter, the adhesion promoter having a phosphoric acid or phosphonic acid group and a group reactable with the non-stick compound; a non-stick coated substrate producible by said method; and the use of said non-stick coated substrate as a tool for embossing or molding micro- or nanostructures.

### FIELD OF THE INVENTION

The present invention relates to a method for producing a non-stick coated substrate, a non-stick coated substrate which can be produced by this method and the use of the non-stick coated substrate as a tool for embossing or forming micro- or nanostructures.

### STATE OF THE ART

US2013280485 A1 discloses a process for producing hydrophobic surfaces by grafting a polymer onto surfaces using initiated chemical vapor deposition (iCVD). The polymer is poly(perfluoroalkyl acrylate) and is produced by polymerization of perfluorinated acrylates.

### Problems to be Solved by the Invention

The present invention is based on the task of providing an effective, conformal and stable non-stick coating on a substrate as well as a method for producing a non-stick coated substrate.

### SUMMARY OF THE INVENTION

The problem was solved by providing a non-stick coated substrate, which is bonded to a non-stick compound via an adhesion promoter, and a process for its manufacture.

The object of the present invention is defined by the following aspects.

[1] A method of preparing a non-stick coated substrate (i.e., a substrate having a non-stick coating) which comprises applying a non-stick compound on a substrate by chemical vapour deposition, wherein the non-stick compound is a surface active compound having a polymerizable group and the substrate is metal-containing and modified with an adhesion promoter, the adhesion promoter having a phosphoric acid or phosphonic acid group and a group reactable with the non-stick compound.

[1-1] The method according to aspect [1], wherein the application of the non-stick compound and the polymerization of the polymerizable group are carried out simultaneously.

[1-2] The method according to any of the preceding aspects, wherein the non-stick compound-reactive group of the adhesion promoter reacts with the polymerizable group of the non-stick compound.

[1-3] The method according to any one of the preceding aspects, wherein upon polymerization of the polymerizable group of the non-stick compound, the group of the adhesion promoter which is reactable with the non-stick compound can be incorporated into the polymer as a polymerizable group.

[1-4] The method according to any one of the preceding aspects, wherein the polymerizable group of the non-stick compound and the group of the adhesion promoter which is reactable with the non-stick compound are the same kind of group.

[1-5] The method according to any one of the preceding aspects, wherein the molecular weight of the non-stick compound is less than 1000 g/mol.

[1-6] The method according to any one of the preceding aspects, wherein the molecular weight of the coupling agent is less than 2000 g/mol.

[1-7] The method according to any of the preceding aspects, wherein the layer thickness of the applied non-stick compound on the substrate is less than 200 nm.

[2] The method according to any of the preceding aspects, wherein the substrate is a metal or a metal alloy.

[3] The method according to any of the preceding aspects, wherein the chemical vapor deposition is an initiated chemical vapor deposition.

[4] The method according to any of the preceding aspects, wherein the non-stick compound is a perfluorinated compound.

[5] The method according to any one of the preceding aspects, wherein the polymerizable group is a polymerizable carbon-carbon double bond.

[5-1] The method according to any of the preceding aspects, wherein the group of the adhesion promoter which can be reacted with the non-stick compound is a carbon-carbon double bond.

[6] The method according to any of the preceding aspects, wherein the non-stick compound is a (meth)acrylic acid ester of a perfluorinated oligoether having at least two CF₃ groups.

[6-1] The method according to aspect [6], wherein the oligoether comprises two to six ether units.

[6-2] The method according to aspect [6] or [6-1], wherein all ether units have a CF₃ group.

[7] The method according to any of the preceding aspects, wherein the non-stick compound is 1H, 1H-perfluoro (2,5-dimethyl-3,6-dioxanonanoyl) acrylate.

[8] The method according to any of the preceding aspects, wherein the coupling agent is a diester of a diol with phosphoric acid and (meth)acrylic acid, a vinylphosphonic acid or an allylphosphonic acid.

[8-1] The method according to aspect [8], wherein the molecular weight of the diol is less than 250 g/mol, preferably less than 100 g/mol.

[9] The method according to one of the preceding aspects, wherein the application of the non-stick compound is carried out using a crosslinking agent.

[9-1] The method according to aspect [9], wherein the polymerizable group of the non-stick compound is a polymerizable carbon-carbon double bond and the crosslinking agent has at least two carbon-carbon double bonds convertible therewith.

[10] The method according to any one of the preceding aspects, wherein the chemical vapor deposition is an initiated chemical vapor deposition, the anti-adhesion compound is a (meth)acrylic acid ester of a perfluorinated oligoether having at least two CF₃ groups, and the adhesion promoter is a diester of a diol with phosphoric acid and (meth)acrylic acid.

[11] A non-stick coated substrate obtainable by a process according to any one of aspects [1] to [10].

[12] The non-stick coated substrate according to aspect [11], which is an embossing tool or molding tool.

[13] The non-stick coated substrate according to aspect [12], wherein the embossing tool or molding tool is suitable for replicating microstructures or nanostructures.

[13-1] A non-stick coated substrate according to aspect [13], wherein the embossing tool or molding tool has protrusions with a height of 1 nm to 200 μm, preferably 10 nm to 100 μm, more preferably 100 nm to 50 μm.

[14] Use of a non-stick coated substrate according to aspect or as a tool for embossing or forming micro- or nanostructures.

[14-1] Use according to aspect [14], wherein the non-stick coating of the tool contacts an embossing lacquer during embossing, which has the microstructures or nanostructures after it has hardened.

[14-2] Use according to aspect [14] or [14-1], wherein the embossing is a UV embossing process.

### Advantages of the Invention

The use of a tool, which is a non-stick coated substrate according to the invention, in an embossing and molding process enables residue-free and defect-free demolding, i.e. the separation of tool and molded material, and thus an improvement in the quality of non-stick coatings.

The non-stick coating has a low layer thickness and shows high conformity, strong hydrophobicity or omniphobicity (i.e. low surface energy) as well as mechanical and chemical stability in multiple UV embossing processes.

The adhesion to the embossing tool and, if necessary, additional cross-linking of the iCVD layer also significantly improve the service life of the non-stick coating and thus the stability of the embossing process.

### EMBODIMENTS OF THE INVENTION

In the process according to the invention, any metal-containing substance that can be modified with the adhesion promoter can be used as a substrate. The metal-containing substance can be a pure metal or an alloy. Examples of metals are nickel, steel, iron, zinc or aluminum.

The non-stick compound is applied by chemical vapor deposition (CVD). Examples of CVD are plasma-enhanced chemical vapor deposition (PECVD) and initiated chemical vapor deposition (iCVD), which is known, for example, from US2013280485 A1. An iCVD process is preferred because it is a gentle and substrate-independent process in which, for example, no damage to the micro- and nanostructures occurs as a result of the plasma treatment. With an iCVD process, a stable, conformal and omniphobic polymer coating can be applied to a substrate. In an iCVD process, an initiator with sufficient vapor pressure can be used, for example selected from the group consisting of tert-butyl peroxide, tert-amyl peroxide, triethylamine, tert-butyl peroxybenzoate, benzophenone and 2,2′-azobis(2-methylpropane).

Usable as a non-stick compound is any compound that can be deposited on a substrate using a chemical vapour deposition process, that is a surface-active compound with the desired non-stick property, and that has a polymerizable group. The non-stick compound may have more than one polymerizable group so that cross-links are formed during polymerization which increase the stability of the coating. The non-stick compound differs from the adhesion promoter. The non-stick compound does not contain a phosphoric acid or phosphonic acid group and/or the adhesion promoter is not significantly surface-active.

Usable as a surface-active compound is any compound that changes the adhesive properties of the surface in a coating on a metal surface. Examples of surface-active compounds are alkanes, polysiloxanes or perfluorinated compounds, whereby perfluorinated compounds and in particular perfluorinated oligoethers are preferred. In this case, the prefix “oligo” denotes two to six, preferably three to six units, which need not be identical. Perfluorinated means that the hydrogen atoms on at least one carbon atom have been completely replaced by fluorine atoms.

The non-stick compounds are usually converted in a polyreaction in which the reactive groups are converted into polymers under the influence of heat, light, ionizing radiation or chemically (via a redox reaction) (addition polymerization).

The polymerizable group may be a carbon-carbon double bond selected from the group consisting of acrylates, methacrylates, vinyl ethers, allyl ethers, propenyl ethers, alkenes, dienes, unsaturated esters, allytriazines, allyl isocyanates and N-vinyl amides. The polymerizable carbon-carbon double bond can be polymerized organically under the influence of light and/or heat and/or by chemical means. It is a group which can be polymerized photochemically under the action of actinic radiation, in particular a UV-polymerizable group. In addition or as an alternative to the polymerization reaction of the carbon-carbon double bonds as such, a reaction of the compounds containing these double bonds with diamines or higher amines or dithiols or higher thiols via a Michael addition (thiol-ene reaction or the analogous reaction with amines) is also possible. The polymerization can therefore also comprise or consist of a thiol-ene reaction, i.e. a reaction of a thiol group with a carbon-carbon double bond. The polymerizable groups in the non-stick compound may be a mixture of thiol groups and carbon-carbon double bonds. It is also possible that the non-stick compound contains double bonds and the adhesion promoter has one or more thiols. In this way, the polymerization and crosslinking of the non-stick compound and the adhesion promoter can be adjusted.

Examples of surface-active compounds with polymerizable groups are alkyl (meth)acrylates, polysiloxane (meth)acrylates, perfluoroalkyl (meth)acrylates, perfluoropolyether (meth)acrylates, alkyl vinyl ethers, polysiloxane vinyl ethers, perfluoroalkyl vinyl ethers and perfluoropolyether vinyl ethers. Preferred are perfluorinated compounds. Examples of perfluorinated non-stick compounds are poly(1H, 1H,2H,2H-perfluorodecyl acrylate) or oligomeric compounds based on hexafluoropropylene oxide (HFPO) such as oligo-HFPO-2-hydroxyethyl methacrylate ester. The exceptional surface activity of this molecule is based on the branched structure of the perfluoropolyether chain with the CF₃ side groups. Further examples are oligo-HFPO urethane acrylates, which are obtained by reacting 2-isocyanatocthyl acrylate with branched tri to hexa-HFPO (oligomer) alcohols having CF₃ side groups. Preferred alcohols are 2-{1,1,2,3,3,3-hexafluoro-2-[1,1,2,3,3,3-hexafluoro-2-(heptafluoropropoxy)propoxy]propoxy}-2,3,3,3-tetrafluoropropan-1-ol (CAS 14620-81-6), 2,4,4,5,7,7,8,10,10,11,13, 13, 14, 14, 15, 15, 15-heptadecafluoro-2,5,8,11-tetrakis(trifluoromethyl)-3,6,9,12-tetraoxapentadecan-1-ol (CAS 141977-66-4) und 1H, 1H-perfluoro (2,5,8,11,14-pentamethyl-3,6,9,12,15-oxaoctadecan-1-ol) (CAS 27617-34-1).

The branched perfluorinated oligo-ether acrylate monomer 1H, 1H-perfluoro (2,5-dimethyl-3,6-dioxanonanoyl) acrylate (CAS number: 17559-01-2) is particularly advantageous as an anti-adhesion compound:

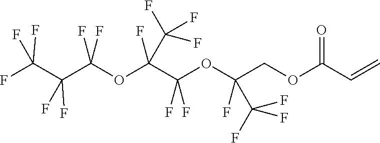 [SMILES: C=CC(=O)OCC(F)(OC(F)(F)C(F)(OC(F)(F)C(F)(F)C(F)(F)F)C(F)(F)F)C(F)(F)F]

The CF₃ side groups and the increased CF₃/CF₂ ratio enable a low surface energy of the deposited polymer layer to be achieved.

The adhesion promoter has a phosphoric acid or phosphonic acid group and a group that can be reacted with the non-stick compound as functional groups. As a rule, these functional groups are linked to each other by a bifunctional coupling group. The phosphoric acid or phosphonic acid group forms a covalent bond with the substrate, and the group that can be reacted with the non-stick compound forms a covalent bond with the non-stick compound. The substrate and the non-stick compound are thus covalently bonded via the adhesion promoter. Preferred adhesion promoters are compounds which are obtained by esterification of phosphonic acid, phosphoric acid and/or polyphosphoric acid, in particular polyphosphoric acid, or anhydrides and/or esters thereof, with a compound containing hydroxyl groups. Preferably, the hydroxy group-containing compound is a polyol, for example a diol, such as an alkanediol, alkanetriol and/or alkanepolyol having 2 to 40 carbon atoms, the hydroxy groups preferably being terminal. Specific compounds containing hydroxy groups are glycol, 1,3-propanediol, 1,4-butanediol, 1,5-pentanediol, 1,6-hexanediol, 1,8-octanediol, 1,10-decanediol, 1,12-dodecanediol, 1,20-cicosanediol, glycerol and trimethylolpropane. The adhesion promoter has a group that can be reacted with the non-stick compound. This group may be a group described above as a polymerizable group of the non-stick compound. An example of an adhesion promoter is phosphoric acid 2-hydroxyethyl methacrylate.

The mechanical stability, in particular the abrasion resistance, and chemical stability of the deposited polymer layer can be improved by adding a crosslinking agent. The crosslinking agent differs from the non-stick compound and the adhesion promoter. In particular, the crosslinking agent is not a surface-active compound and does not contain a phosphoric acid or phosphonic acid group. Preferred crosslinking agents are DEGDVE (di(ethylene glycol) divinyl ether) and/or V4D4 (1,3,5,7-tetravinyl-1,3,5,7-tetramethylcyclotetrasiloxane). The iCVD copolymerization of the perfluorinated oligoetheralkyl acrylate together with one of the preferred crosslinking agent molecules results in extremely stable coatings with extremely low surface energy.

The method according to the invention can be used to produce a substrate having a non-stick coating. This non-stick coated substrate can be used as an embossing tool or forming tool for the replication of micro- or nanostructures, for example in a nano embossing lithography process. Micro- or nanostructures are structures that have indentations with a depth in the nanometer or micrometer range, for example a depth of 0.1 nm to 200 μm, preferably 10 nm to 100 μm, more preferably 100 nm to 50 μm.

### EXAMPLES

A process according to the invention was carried out. A polymer layer was deposited on a nickel surface using iCVD. The polymer was formed from 1H, 1H-perfluoro (2,5-dimethyl-3,6-dioxanonanoyl) acrylate.

The non-stick coating deposited by iCVD showed excellent conformity, which was demonstrated by measurements with an atomic force microscope (AFM) on the embossing tool before and after deposition.

The polymer layer had a high water contact angle of 109° and a low surface energy of around 12.6 mJ/m². This means that excellent hydrophobization and thus a reduction in surface energy was achieved. In comparison, the water contact angle on an uncleaned nickel surface is typically about 50°, and the water contact angle on a nickel surface cleaned and activated by plasma or basic piranha treatment is about 25°.

A series of UV embossings were carried out in a representative acrylate-based UV embossing varnish. The contact angles of seated water and diiodomethane droplets were measured at regular intervals. It was found that the contact angle remained virtually unchanged between the first and the hundredth impression. This result proves the stability of the non-stick coating in UV embossing processes.

The water contact angle is calculated using the ORWK method. In the present invention, the surface energies are determined using the method according to Owens, Wendt, Rabel and Kaelble (OWRK) (D. H. Kaelble, Dispersion-Polar Surface Tension Properties of Organic Solids. In: J. Adhesion 2 (1970), pp. 66-81; D. Owens, R. Wendt, Estimation of the Surface Free Energy of Polymers. In: J. Appl. Polym. Sci 13 (1969), pp. 1741-1747; W. Rabel, Einige Aspekte der Benetzungstheorie und ihre Anwendung auf die Untersuchung und Veränderung der Oberflächeneigenschaften von Polymeren. In: Farbe und Lack 77,10 (1971), pp. 997-1005). The OWRK method is a standard method for calculating the surface free energy of a solid from the contact angle with several liquids. The surface free energy is split into a polar component and a disperse component.

What is claimed is:

1. A method of preparing a non-stick coated substrate which comprises applying a non-stick compound on a substrate by chemical vapour deposition, wherein the non-stick compound is a surface active compound having a polymerizable group and the substrate is metal-containing and modified with an adhesion promoter, the adhesion promoter having a phosphoric acid or phosphonic acid group and a group reactable with the non-stick compound.

2. The method according to claim 1, wherein the substrate is a metal or a metal alloy.

3. The method according to claim 1, wherein the chemical vapor deposition is an initiated chemical vapor deposition.

4. The method according to claim 1, wherein the non-stick compound is a perfluorinated compound.

5. The method according to claim 1, wherein the polymerizable group is a polymerizable carbon-carbon double bond.

6. The method according to claim 1, wherein the non-stick compound is a (meth)acrylic acid ester of a perfluorinated oligoether having at least two CF₃ groups.

7. The method according to claim 1, wherein the non-stick compound is 1H,1H-perfluoro (2,5-dimethyl-3,6-dioxanonanoyl) acrylate.

8. The method according to claim 1, wherein the adhesion promoter is a diester of a diol with phosphoric acid and (meth)acrylic acid.

9. The method according to claim 1, wherein the application of the non-stick compound is carried out using a crosslinking agent.

10. The method according to claim 1, wherein the chemical vapor deposition is an initiated chemical vapor deposition, the non-stick compound is a (meth)acrylic acid ester of a perfluorinated oligoether having at least two CF₃ groups and the adhesion promoter is a diester of a diol with phosphoric acid and (meth)acrylic acid.

11. A non-stick coated substrate obtainable by a method according to claim 1.

12. The non-stick coated substrate according to claim 11, which is an embossing tool or forming tool.

13. The non-stick coated substrate according to claim 12, wherein the embossing tool or molding tool is suitable for replication of micro- or nanostructures.

14. Use of a non-stick coated substrate according to claim 11 as a tool for embossing or forming micro- or nanostructures.
